(19) United States
(12) Patent Application Publication
(10) Pub. No.: US 2011/0285430 A1
(43) Pub. Date: Nov. 24, 2011

(54) HOT-SWAP CONTROLLER

(75) Inventor: Junichi Todaka, Oita-ken (JP)

(73) Assignee: KABUSHIKI KAISHA TOSHIBA, Tokyo (JP)

(21) Appl. No.: 13/024,476

(22) Filed: Feb. 10, 2011

(30) Foreign Application Priority Data
May 24, 2010 (JP) 2010-118699

(51) Int. Cl. H03L 7/00

(52) U.S. Cl. 327/143

(57) ABSTRACT

According to one embodiment, a hot-swap controller includes an output circuit, a voltage generator, a detector, and a compensator. The output circuit is configured to generate an enabling signal. The enabling signal is capable of switching an output signal of a semiconductor device provided on a hot-swap board to be disabled when a supply voltage is lower than a release voltage and to be enabled when the supply voltage is higher than the release voltage. The voltage generator includes a bias transistor supplied with the supply voltage and is configured to generate a first voltage. The first voltage varies depending on the supply voltage and is referred to detect the release voltage. The detector is configured to detect the first voltage. The compensator is configured to compensate the first voltage to a certain value depending on an output of the detector.

### CROSS-REFERENCE TO RELATED APPLICATIONS

This application is based upon and claims the benefit of priority from the prior Japanese Patent Application No. 2010-118699, filed on May 24, 2010; the entire contents of which are incorporated herein by reference.

### FIELD

Embodiments described herein relate generally to a hot-swap controller.

### BACKGROUND

In recent years, circuit boards and devices having hot-swap functionality are removable while power sources are supplied to device bodies. For example, in communication systems, data processing systems, etc., by the hot-swap functionality, the circuit boards and devices in which failures have occurred can be removed to replace while power sources are supplied without stopping systems. Further, systems can be expanded by adding new modularized boards.

In the case where a board (hot-swap board) side performing hot-swap is capable of outputting, i.e., enabled, an incorrect operation may occur on a main board side because the output of the hot-swap board side is transmitted to the main board side when a supply voltage is too low for metal-oxide-semiconductor field-effect transistors (MOSFETs) to operate properly.

Therefore, in the case where the hot-swap board is inserted and extracted, a hot-swap controller is used to make the output of the hot-swap board side disabled until the supply voltage is stabilized.

However, threshold voltages of complementary metal oxide semiconductors (CMOSs) vary with production process and the like. Therefore, the supply voltage at which the output of the hot-swap board side is changed from being disabled to being enabled or from being enabled to being disabled (hereinbelow, release voltage) may vary, and a logical level of the voltage output from the hot-swap board side may be erroneously decided.

### BRIEF DESCRIPTION OF THE DRAWINGS

FIG. 1 is a circuit diagram illustrating the configurations of hot-swap controllers according to first and second embodiments;

FIG. 2 is a circuit diagram of a hot-swap controller of a comparative example;

FIG. 3 is a graph illustrating simulation results of a release voltage VRD due to variation of production process of the comparative example;

FIG. 4 is a graph illustrating simulation results of a release voltage VRD due to variation of production process of the hot-swap controller illustrated in FIG. 1;

FIG. 5 is a circuit diagram illustrating another configuration of the hot-swap controller according to the second embodiment; and

FIG. 6 is a circuit diagram illustrating another configuration of the hot-swap controller according to the second embodiment.

### DETAILED DESCRIPTION

In general, according to one embodiment, a hot-swap controller includes an output circuit, a voltage generator, a detector, and a compensator. The output circuit is configured to generate an enabling signal. The enabling signal is capable of switching an output signal of a semiconductor device provided on a hot-swap board to be disabled when a supply voltage is lower than a release voltage and to be enabled when the supply voltage is higher than the release voltage. The voltage generator includes a bias transistor supplied with the supply voltage and is configured to generate a first voltage. The first voltage varies depending on the supply voltage and is referred to detect the release voltage. The detector is configured to detect the first voltage. The compensator is configured to compensate the first voltage to a constant value depending on an output of the detector.

Embodiments will now be described in detail with reference to the drawings. In the specification and the drawings of the application, components similar to those described in regard to a drawing thereinabove are marked with like reference numerals, and a detailed description is omitted as appropriate.

### First Embodiment

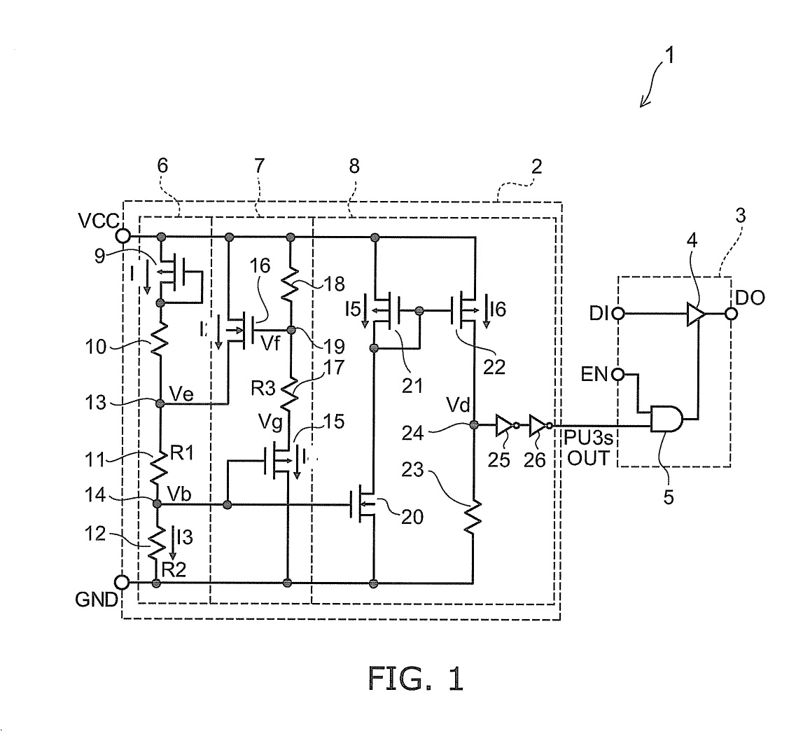

FIG. 1 is a circuit diagram illustrating the configurations of hot-swap controllers according to first and second embodiments.

The configurations of a hot-swap controller 1 according to the first embodiment and a hot-swap controller 2 according to the second embodiment are illustrated in FIG. 1.

The hot-swap controller 1 includes an interface circuit 3, a voltage generator 6, a detector 7, a compensator 16, and an output circuit 8. A structure may be provided in which the hot-swap controller 1 is formed on a semiconductor substrate in one chip and is mounted on a hot-swap board (not illustrated). The hot-swap controller 1 is mounted on a hot-swap board (not illustrated) extracted from and inserted into a main board of a system, such as, for example, a communication system and data processing system.

The interface circuit 3 includes a 3-state circuit 4 and a logical product circuit (AND) 5.

The 3-state circuit 4 receives a signal DI from a logical circuit of a semiconductor device (not illustrated) in the hot-swap board. The 3-state circuit 4 outputs a signal DO. A control terminal of the 3-state circuit 4 is connected to an output of the AND 5 and receives the logical product of an enabling signal PU3sOUT and a control signal EN.

The enabling signal PU3sOUT is generated by the voltage generator 6, the detector 7, the compensator 16, and the output circuit 8. As described below, the interface circuit 3 receives the enabling signal PU3sOUT, which becomes a low level or high level depending on a value of the supply voltage VCC, and the output state of the 3-state circuit 4 is controlled to be enabled or disabled. The output state of the 3-state circuit 4 is controlled to be disabled when the supply voltage is lower than the release voltage VRD and controlled to be enabled when the supply voltage is higher than the release voltage VRD. The control signal EN is input from one other logical circuit (not illustrated) in the hot-swap board. The signal DO output from the 3-state circuit 4 is the signal output from the hot-swap board side to the main board side in the case where the hot-swap board is inserted into the main board (not illustrated).

The control signal EN is the signal that controls the output of the signal from the hot-swap board to the main board when the enabling signal PU3sOUT is high level. When the control signal EN is high level, the 3-state circuit 4 is enabled and the signal DI is output as the signal DO from the hot-swap board side to the main board side. When the control signal EN is low level, the 3-state circuit 4 is disabled and the output of the 3-state circuit 4 is in a high-impedance state.

Next, the operation of the interface circuit 3 of the hot-swap controller 1 will be described.

First, the case where the system power of the main board side is in the ON state and the hot-swap board is inserted into the energized main board is described. The supply voltage VCC of the hot-swap controller 1 ramps up from 0 V to the supply voltage supplied from the main board when the hot-swap board is inserted into the main board.

Here, the supply voltage VCC indicates the instantaneous value of the supply voltage that is actually supplied to the hot-swap controller 1. The supply voltage VCC is discharged at 0 V before the hot-swap board is inserted into the main board and is charged up to the supply voltage supplied from the main board after the hot-swap board is inserted into the main board. The supply voltage VCC of the hot-swap board is different from the supply voltage supplied from the main board until reaching a steady-state value through the charge time. An incorrect operation may occur at a time when the supply voltage VCC ramps up from 0 V to the supply voltage supplied from the main board.

CMOSs generally become active at, for example, approximately 0.8 V. Therefore, each of circuits starts operation to output high level or low level when the supply voltage VCC ramps up at 0.8 V. However, the voltage output as high level is limited to the value of the supply voltage VCC that is actually supplied to the hot-swap board. Therefore, the hot-swap board can output only up to 0.8 V. Accordingly, for example, if the signal DO of 0.8 V is output in this situation from the interface circuit 3 to the main board side of 5 V standard, the main board side may detect the output of 0.8 V as low level and lead an incorrect operation.

To realize the hot-swap functionality, it is necessary for the output from the hot-swap board to keep a high-impedance state until the voltage output from the hot-swap board reaches a specified value at which the main board detects as high level. For example, when the input of the main board side is pulled up, it is necessary for the output from the hot-swap board to keep the high-impedance state until the supply voltage VCC reaches 1.5 V of the specified value (in the case of 5 V standard).

Further, in the case where the hot-swap board is extracted from the main board, the supply voltage VCC of the hot-swap board ramps down from the steady-state value of the supply voltage supplied from the main board to 0 V. At this time, it is necessary for the output from the hot-swap board to be in the high-impedance state in the case where the voltage output from the hot-swap board is lower than the specified value at which the main board side detects as high level.

Therefore, in the interface circuit 3 of the hot-swap controller 1, the output from the hot-swap board is controlled to the high-impedance state when the value of the supply voltage VCC is not higher than the specified value at which the main board side detects as high level during power up and power down.

For example, in the case where the main board side is 5 V standard, in the interface circuit 3, the output from the hot-swap board is controlled to the high-impedance state when the supply voltage VCC is from 0 V to 1.5 V and lower than the specified value. Further, for example, in the case where the main board side is 3 V standard, in the interface circuit 3, the output from the hot-swap board is controlled to the high-impedance state when the supply voltage VCC is from 0 V to 1.2 V and lower than the specified value.

As described above, the supply voltage at which the enabling signal PU3sOUT changes from high level to low level or from low level to high level is a voltage at which the output of the interface circuit 3 is released from the high-impedance state, i.e., the release voltage VRD. The release voltage VRD is a voltage output from the interface circuit 3 when the signal DI of high level is input to the interface circuit 3 and the interface circuit 3 starts to output the signal DO of high level.

In the hot-swap controller 1, the output state of the interface circuit 3 is controlled by the enabling signal PU3sOUT. Therefore, in the case where the input of the main board side is pulled down, the hot-swap functionality is secured even when the output from the interface circuit 3 is high level. Further, in the hot-swap controller 1, the enabling signal PU3sOUT is output from the hot-swap controller 2, which includes a voltage generator 6, a detector 7, a compensator 16, and an output circuit 8, according to the second embodiment.

As described below, variations of the release voltage VRD at which the enabling signal PU3sOUT changes from low level to high level or from high level to low level is compensated. Therefore, the main board neither falsely detects the high level voltage output from the interface circuit 3 as low level and nor operates incorrectly.

### Second Embodiment

The hot-swap controller 2 according to the second embodiment includes a voltage generator 6, a detector 7, an output circuit 8, and a compensator 16. The hot-swap controller 2 outputs the enabling signal PU3sOUT of which logical value is low level or high level depending on the value of the supply voltage VCC.

The voltage generator 6 includes a transistor (bias transistor) 9, a resistor 10, a first resistor 11, and a second resistor 12.

The transistor 9 is a P-channel MOSFET (hereinbelow, PMOS) and the supply voltage VCC is supplied to its source. The gate and the drain are connected to one terminal of the resistor 10. One other terminal of the resistor 10 is connected to one terminal of the first resistor 11. The transistor 9 and the resistor 10 are supplied with the supply voltage VCC, and a first current I1 that varies depending on the supply voltage VCC is supplied to the one terminal of the first resistor 11, i.e., a connection node 13 of the resistor 10 and the first resistor 11.

In the voltage generator 6, the first current I1 that varies depending on the supply voltage VCC is supplied to the one terminal of the first resistor 11 by supplying the supply voltage VCC to the transistor 9 and the resistor 10. However, it is sufficient that the first current I1, which varies depending on the supply voltage VCC, is supplied to the one terminal of the first resistor 11; and the transistor 9 can be all that is needed.

The second resistor 12 is connected between the one other terminal of the first resistor 11 and the ground. The first resistor 11 and the second resistor 12 are connected in series at a connection node 14. A first voltage Vb is generated across the second resistor 12.

As described below, the first voltage Vb is input to the output circuit 8, converted into a digital signal becoming low level or high level depending on the supply voltage VCC, and output as the enabling signal PU3sOUT.

The detector 7 includes a first transistor (detection transistor) 15, a third resistor (detection resistor) 17, and a fourth resistor (detection resistor) 18.

The first transistor 15 is a PMOS, and its gate is connected to the connection node 14 of the first resistor 11 and the second resistor 12. The drain of the first transistor 15 is connected to the ground, and the source is connected to one terminal of the third resistor 17.

One other terminal of the third resistor 17 is connected to one terminal of the fourth resistor 18, and one other terminal of the fourth resistor 18 is supplied with the supply voltage VCC.

The current I4 flows through the first resistor 15, the third resistor 17, and the fourth resistor 18 when the gate-source voltage of the first transistor 15 is equal to or higher than a threshold voltage.

The current I4 causes to generate a voltage Vf at a connection node 19 of the third resistor 17 and the fourth resistor 18. The first transistor 15 is connected between the third resistor 17 and the ground, detects the first voltage Vb, outputs the current I4 to the third resistor 17 depending on the first voltage Vb, and generates the voltage Vf at the connection node 19.

The compensator 16 consists of a second transistor (feedback transistor) 16 and compensates the first voltage Vb to a constant value depending on an output of the detector 7. Here, the compensation of the first voltage Vb to a constant value is to suppress variation of the first voltage due to variation of parameters of MOSFETs from production process etc., as described below. The second transistor 16 is an N-channel MOSFET (hereinbelow, NMOS), and its gate is connected to the connection node 19 of the third resistor 17 and the fourth resistor 18. The drain of the second transistor 16 is supplied with the supply voltage VCC. The source of the second transistor 16 is connected to the connection node 13 of the resistor 10 of the voltage generator 6 and the first resistor 11.

The second transistor 16 is controlled by the voltage Vf of the connection node 19 of the output of the detector 7 and compensates the first voltage Vb to a constant value with respect to a given value of the supply voltage VCC by feeding back a second current I2 to the connection node 13 of the voltage generator 6, i.e., the one terminal of the first resistor 11.

The detector 7 and the compensator 16 constitute a feedback circuit across the first resistor 11. The feedback circuit detects variation of the first voltage Vb due to variation of production process etc. of the hot-swap controller 2 with respect to the given value of the supply voltage VCC and negatively feeds back the second current I2 to the one terminal of the first resistor 11. The resultant current I1+I2 of the first current I1, which flows through the first resistor 11, and the second current I2, which flows through the second resistor 12, is controlled to a constant value, and the first voltage Vb is controlled to a constant value. Therefore, the variation of the first voltage Vb due to variation of production process etc. of the hot-swap controller 2 is compensated.

Further, the second current I2 is positively fed back with respect to variation of the supply voltage VCC, and the resultant current I1+I2 flowing through the first resistor 11 and the second resistor 12 is controlled depending on the supply voltage VCC. Therefore, the first voltage Vb is compensated to a value depending on the supply voltage VCC.

The output circuit 8 includes a fourth transistor (output transistor) 20, transistors 21 and 22, a fifth resistor 23, and inverters 25 and 26.

The fourth transistor 20 is a NMOS, and its gate is connected to the connection node 14 of the voltage generator 6. The source of the fourth transistor 20 is connected to the ground, and its drain is connected to the drain of the transistor 21. The first voltage Vb is supplied between the gate and the source of the fourth transistor 20. The transistors 21 and 22 are PMOSs and constitute a current mirror.

The fifth resistor 23 is connected between the drain of the transistor 22 and the ground. An input of the inverter 25 is connected to a connection node 24 of the drain of the transistor 22 and the fifth resistor 23. An output of the inverter 25 is connected in cascade to inverter 26, and the inverter 26 outputs the enabling signal PU3sOUT.

The output circuit 8 generates the enabling signal PU3sOUT, which can switch, for example, an output signal of a semiconductor device provided on the hot-swap board to be disabled when the supply voltage VCC is lower than the release voltage VRD and to be enabled when the supply voltage VCC is higher than the release voltage VRD.

The enabling signal PU3sOUT is high level when the first voltage Vb is higher than a logical threshold of the output circuit 8 and low level when the first voltage Vb is lower than the logical threshold of the output circuit 8. The output circuit 8 inputs the first voltage Vb, which is converted into a digital signal that becomes low level or high level depending on the value of the supply voltage VCC, and outputs the enabling signal PU3sOUT.

The output circuit 8 determines whether the supply voltage VCC is higher than the release voltage VRD or not by detecting the value of the first voltage Vb input. The first voltage Vb that changes depending on the supply voltage VCC is a reference with which the release voltage VRD is detected.

Next, an operation of the hot-swap controller 2 will now be described.

The hot-swap controller 2 is provided on a board (hot-swap board) side inserted and extracted from a main board of a system, such as, for example, a communication system and a data processing system.

The case where the power source of the system is in the ON state and the hot-swap board is inserted into the energized main board is described.

When the hot-swap board is inserted, the supply voltage VCC of the hot-swap controller 2 ramps up from 0 V to the value of the steady-state of the supply voltage supplied from the main board. The one terminal (connection node 13) of the first resistor 11 of the voltage generator 6 is supplied with the supply voltage VCC via the resistor 9 and the resistor 10. Therefore, the one terminal of the first resistor 11 is supplied with the first current I1, which varies depending on the supply voltage VCC. The first current I1 supplied from the resistor 10 increases as the supply voltage VCC rumps up.

The second current I2 is fed back from the second transistor (feedback transistor, compensator) 16 to the one terminal (connection node 13) of the first resistor 11.

The resultant current I3=I1+I2 of the first current I1 and the second current I2 flows through the first resistor 11 and the second resistor 12, and the first voltage Vb is generated across the second resistor 12.

The fourth transistor 20 remains in the OFF state until the first voltage Vb exceeds the threshold voltage of the fourth transistor 20 of the output circuit 8. A voltage across the fifth resistor 23 is lower than a logical threshold of the inverter 25 because current does not flow through the current mirror consisting of the transistors 21 and 22, and the fifth resistor 23. Therefore, an input of the inverter 25 is low level, and the enabling signal PU3sOUT output from the inverter 26 is low level.

The first voltage Vb ramps up as the supply voltage VCC ramps up. The fourth transistor 20 is turned on when the first voltage vb exceeds the threshold voltage of the transistor 20 of the output circuit 8.

Current I5 flows through the transistor 21 of a reference side of the current mirror by turning on the fourth transistor 20. The current I5 is replicated by the current mirror, and current I6 flows from the transistor 22 to the fifth resistor 23.

A voltage Vd across the fifth resistor 23 exceeds the logical threshold of the inverter 25 and becomes high level. Therefore, the output of the inverter 25 changes from high level to low level, and the enabling signal PU3sOUT output from the inverter 26 changes from low level to high level. In this case, the enabling signal PU3sOUT output from the inverter 26 is nearly equal to the supply voltage VCC.

Then, the enabling signal PU3sOUT ramps up as the supply voltage VCC ramps up.

The supply voltage VCC and the enabling signal PU3sOUT ramp up to the supply voltage supplied from the main board and becomes the steady-state value.

Further, in the case where the hot-swap board is extracted from the main board, the supply voltage VCC ramps down form the steady-state value of the supply voltage supplied from the main board to 0 V, in an opposite manner as previously described. The voltage Vd across the fifth resistor also ramps down, and when the voltage Vd is lower than the logical threshold of the inverter 25, the enabling signal PU3sOUT changes from high level to low level. Then, the enabling signal PU3sOUT ramps down to 0 V.

As described above, the current I6 flows through the fifth resistor 23 depending on the first voltage Vb, and when the voltage Vd across the fifth resistor 23 exceeds the logical threshold of the inverter 25, the enabling signal PU3sOUT changes from low level to high level. Further, the enabling signal PU3sOUT changes from high level to low level when the voltage Vd across the fifth resistor 23 is lower than the logical threshold of the inverter 25. The supply voltage VCC at which the enabling signal PU3sOUT changes from low level to high level or from low level to high level is the release voltage VRD as described above.

Therefore, for reducing the variation (or deviation) of the release voltage VRD due to production process, etc., the first voltage Vb has to be compensated with respect to variation of production process etc.

In the hot-swap controller 2, the resultant current I1+I2 of the first current I1 and the second current I2 is controlled to a constant value with respect to the given value of the supply voltage VCC by the feedback circuit that consists of the detector 7 and the compensator (second transistor, feedback transistor) 16 and negatively feeds back the second current I2.

The first transistor 15 of the detector 7 detects the first voltage Vb. The compensator (second transistor, feedback transistor) 16 is controlled by the output of the first transistor 15 and feeds back the second current I2 to the one terminal of the first resistor 11 of the voltage generator 6. Thereby, the variation of the first voltage Vb is compensated. Further, the first voltage Vb is compensated to a value depending on the supply voltage VCC by positively feeding back the second current I2 with respect to variation of the supply voltage VCC.

The first voltage Vb is generated by synthesizing the resultant current I3=I1+I2 of the second current I2 and the first current I1 supplied via the resistor 10. Therefore, the first voltage Vb is regulated and compensated to suppress variation, which may be caused by variation of production process, of the release voltage VRD.

Next, operation analyzes of the hot-swap controller 2 will be described.

The transconductances of the first and the second transistors 15 and 16 are taken as gm1 and gm2, respectively. The threshold voltages of the first and the second transistors 15 and 16 are taken as VthP and VthN, respectively. Further, the first voltage (voltage of the connection node 14), a voltage of the connection node 13, the gate voltage of the second transistor 16, and the source voltage of the first transistor 15 are taken as Vb, Ve, Vf, and Vg, respectively.

Then, the second current I2 of the second transistor 16 is given by equation (1).

I2=(gm2/2)×(Vf−Ve−VthN) (1)

Then, the current I4 of the first transistor 15 is given by equation (2).

I4=(gm1/2)×(Vg−Vb−VthP) (2)

Further, the first current supplied from the supply voltage VCC via the transistor 9 and the resistor 10 is taken as I1, the current flowing through the first resistor 11 and the second resistor 12 is taken as I3=I1+I2. Further, resistances of the first to third resistors 11, 12 and 17 are taken as R1, R2, and R3, respectively. In the situation just described, the first voltage Vb, the voltage Ve of the one terminal of the first resistor 11 (connection node 13), the gate voltage Vf of the second transistor 16, and the source voltage Vg of the first transistor 15 satisfy following equations (3) to (5).

Ve−Vb=I3×R1=(I1+I2)×R1 (3)

Vb=I3×R2=(I1+I2)×R2 (4)

Vf−Vg=I4×R3 (5)

Elimination of the first voltage Vb, the voltage Ve of the connection node 13, the gate voltage Vf of the second transistor 16, and the source voltage Vg of the first transistor 15 from the equations (1) to (5) gives equation (6).

I2×(1+(gm2/2)×R1)=(gm2/2)×(−I1×R1+I4×(R3+(2/gm1)+VthP−VthN)) (6)

Further, configuring to satisfy relation of 1<<(gm2/2)×R1, equation (6) is simplified as equation (7).

I2=(I4×(R3+(2/gm1))+VthP−VthN)/R1−I1 (7)

Equation (7) shows that the affection on the current I3=I1+I2 flowing through the first and second resistors 11 and 12 by the variation of product process is reduced and constant current characteristics are maintained. For example, in the case where the first current I1 supplied to the one terminal of the first resistor 11 via the transistor 9 and the resistor 10 increases due to affection of the variation of product process, the feedback of the second current I2 from the second transistor 16 decreases. Alternatively, in the case where the first current I1 supplied to the one terminal of the first resistor 11 via the transistor 9 and the resistor 10 decreases, the feedback of the second current I2 from the second transistor 16 increases.

Therefore, the variation of the first voltage Vb is compensated, and the variation of the release voltage VRD due to product process is compensated and reduced.

Further, in the feedback circuit which consists of the detector 7 and the compensator (second transistor, feedback transistor) 16, the first and second transistors 15 and 16 of different channel types are serially inserted in the path in which variation of the first voltage Vb with respect to the given value of the supply voltage VCC is detected and the second current I2 is fed back.

This results in division of the difference of (VthP−VthN) by the resistance R1 of the first resistor 11, with respect to the threshold voltages VthP and VthN of the first and second transistors 15 and 16, as shown by equation (7). Therefore, the variation of the release voltage VRD is also compensated and reduced with respect to threshold voltages of MOSFETs, which constitute a considerable fraction of the variation of the product process.

Here, as a comparative example, a hot-swap controller including no feedback circuit, which consists of the detector 7 and the compensator 16, will be described.

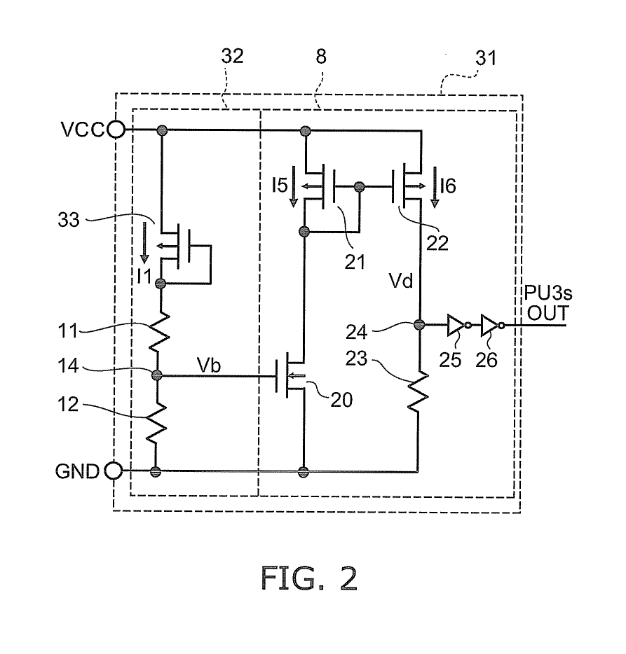

FIG. 2 is a circuit diagram of the hot-swap controller of the comparative example.

As illustrated in FIG. 2, the hot-swap controller 31 of the comparative example includes a voltage generator 32 and an output circuit 8. The hot-swap controller 31 of the comparative example has a configuration in which the detector 7 and the compensator 16 of the hot-swap controller 2 illustrated in FIG. 1 are absent and the voltage generator 6 is replaced with the voltage generator 32. The output circuit 8 is similar to that of the hot-swap controller 2 illustrated in FIG. 1.

The voltage generator 32 includes a transistor 33 and first and second resistors 11 and 12. The voltage generator 32 has a configuration in which the resistor 10 of the voltage generator 6 illustrated in FIG. 1 is shorted.

The transistor 33 is a PMOS, its source is supplied with a supply voltage VCC, and its gate and drain are connected to one terminal of a first resistor 11. The transistor 33 is supplied with the supply voltage VCC and supplies a first current I1 to the one terminal of the first resistor 11.

One other terminal of the first resistor 11 is connected to one terminal of a second resistor 12, one other terminal of the second resistor 12 is connected to a ground. The first resistor 11 and the second resistor 12 are connected in series. A first voltage Vb is generated across the second resistor 12.

In the case of power-off, the first voltage Vb and an enabling signal PU3sOUT are 0 V because no current flows between the power supply and the ground of the hot-swap controller 31.

In the case of powering up, the supply voltage VCC ramps up from 0 V, and the first current I1 between the power supply and the ground of the voltage generator 32 via the transistor 33, the first resistor 11 and the second resistor 12 starts to increase.

The supply voltage VCC ramps up, and when a voltage (threshold voltage) at which the fourth transistor 20 of the output circuit 8 is turned on is obtained, current I5 flows through a path between the power supply and the ground via the fourth transistor 20 and a transistor 21 of the output circuit 8.

The transistors 21 and 22 constitute a current mirror, and current I6 flows through a path between the power supply and the ground via the transistor 22 and a fifth resistor 23. The enabling signal PU3sOUT output from an inverter 26 becomes high level when a voltage Vd across the fifth resistor 23 exceeds a logical threshold of an inverter 25.

However, a gate/source voltage of the fourth transistor 20 is equal to the first voltage Vb and is determined by the first current I1 supplied from the supply voltage VCC. Therefore, if variation of production process etc., causes to vary the first current I1, the enabling signal PU3sOUT varies and the supply voltage at which the enabling signal PU3sOUT changes from low level to high level i.e., release voltage VRD, also varies. Although the case of powering up is described, the case of powering down is carried out in a similar manner.

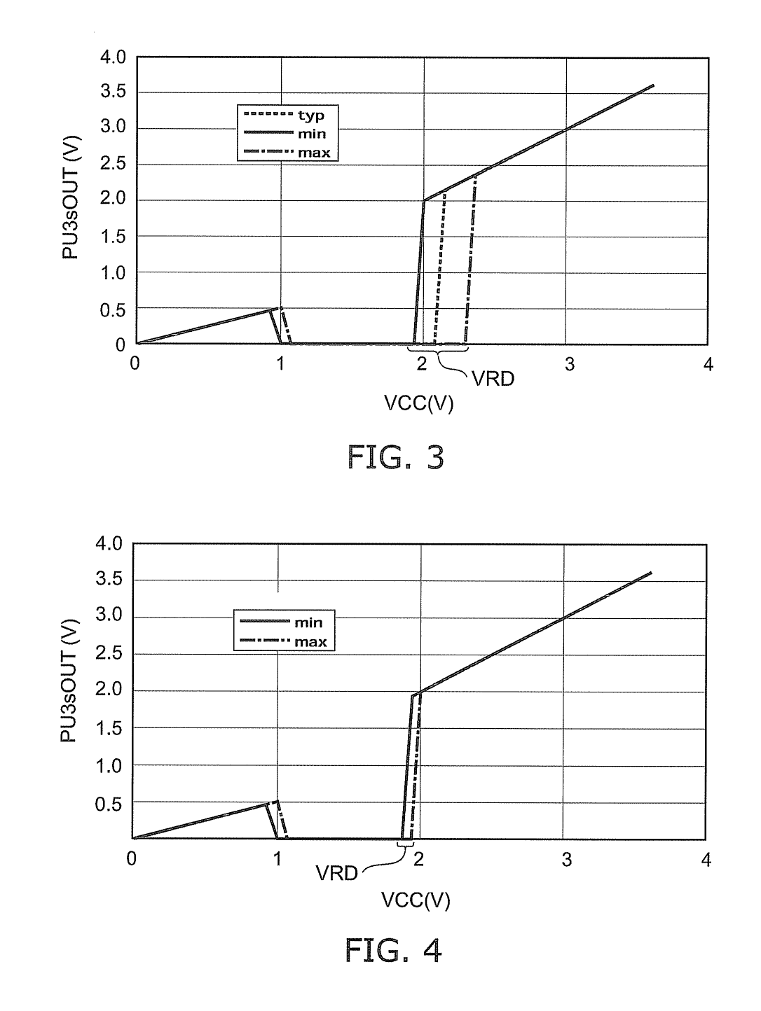

FIG. 3 is a graph illustrating simulation results of a release voltage VRD due to variation of production process of the comparative example.

FIG. 3 shows simulation results of variations of a release voltage VRD due to variation of production process, where the horizontal axis represents the supply voltage VCC and the vertical axis represents the voltage of the enabling signal PU3sOUT. The threshold voltages VthP and VthN of the first and second transistors 15 and 16 show each case of process center condition (typ), process minimal condition (min), and process maximum condition (max).

The process center condition (typ) is the case where the threshold voltages VthP and VthN of the first and second transistors 15 and 16 both are a central value. The process minimum condition (min) is the case where the threshold voltages VthP and VthN of the first and second transistors 15 and 16 both are a minimum value. The process maximum condition (max) is the case where the threshold voltages VthP and VthN of the first and second transistors 15 and 16 both are a maximum value.

As illustrated in FIG. 3, the supply voltage at which the enabling signal PU3sOUT changes from low level to high level or from high level to low level i.e., the value of the release voltage VRD varies in the cases of min and max. As described in FIG. 2, the first voltage Vb and the voltage at which the fourth transistor 20 is turned on are determined by the first current I1. Therefore, variation of the product process etc. causes to vary the first current I1, and the release voltage VRD varies.

If variation of the release voltage VRD is large, there may be a case where the value of the release voltage VRD is lower than the specified value (e.g., 1.5 V in the case of 5 V standard) at which the main board side detects as high level. Alternatively, there may be a case where the value of the release voltage VRD is lower than a minimum value of an operation supply voltage of the hot-swap controller 31. In the case where variation is large as illustrated in FIG. 3, the release voltage VRD in the case of the min needs to be higher than the specified value of 1.5 V.

FIG. 4 is a graph illustrating simulation results of a release voltage VRD due to variation of production process of the hot-swap controller illustrated in FIG. 1.

FIG. 4 shows simulation results of variations of a release voltage VRD due to variation of production process, where the horizontal axis represents the supply voltage VCC and the vertical axis represents the enabling signal PU3sOUT. The threshold voltages VthP and VthN of the first and second transistors 15 and 16 show each case of process minimal condition (min), and process maximum condition (max). The simulation conditions are the same as the cases of the comparative example illustrated in FIG. 3.

The variation of the supply voltage at which the enabling signal PU3sOUT changes from low level to high level or from high level to low level i.e., the release voltage VRD is reduced with compared to the cases of the comparative example illustrated in FIG. 3. As a result, the release voltages VRD in the cases of min and max need not be so high for 1.5 V of the specified value

The variation due to product process includes variations of gate oxide film thicknesses, gate lengths etc. beside the threshold voltages of the first and second transistors 15 and 16. However, because these also cause to vary the first current I1, the variation of the release voltage VRD is compensated and reduced by the hot-swap controller 2.

### Second Example of the Second Embodiment

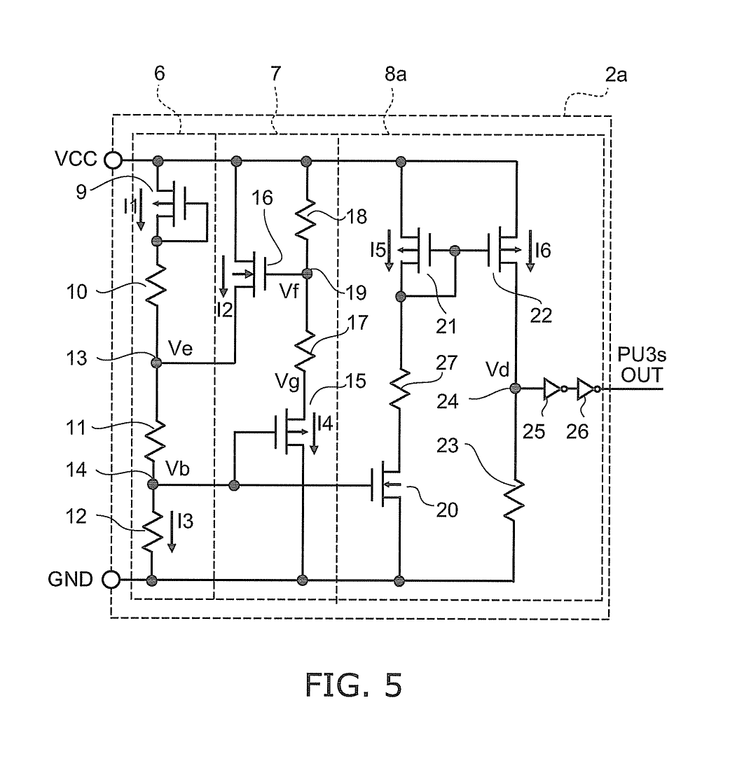

FIG. 5 is a circuit diagram illustrating another configuration of the hot-swap controller according to the second embodiment.

As illustrated in FIG. 5, the hot-swap controller 2a according to the second embodiment includes a voltage generator 6, a detector 7, an output circuit 8a, and a compensator 16. The hot-swap controller 2a has a configuration in which the output circuit 8 of the hot-swap controller 2 illustrated in FIG. 1 is replaced with the output circuit 8a.

Similarly to the hot-swap controller 2 illustrated in FIG. 1, the hot-swap controller 2a can be used to control the interface circuit 3.

The output circuit 8a includes a fourth transistor (output transistor) 20, transistors 21 and 22, a fifth resistor 23, inverters 25 and 26, and a resistor (current-limit resistor) 27.

The fourth transistor 20 is a NMOS, and its gate is connected to a connection node 14 of the voltage generator 6. The source of the fourth transistor 20 is grounded, and its drain is connected to the drain of the transistor 21 via the resistor 27. The transistors 21 and 22 are PMOSs and constitute a current mirror.

The fifth resistor 23 is connected between the drain of the transistor 22 and the ground. An input of the inverter 25 is connected a connection node 24 of the drain of the transistor 22 and the fifth resistor 23. The inverter 26 is connected to an output of the inverter 25 in cascade and outputs the enabling signal PU3sOUT.

The output circuit 8a has a configuration in which the resistor 27 is inserted between the fourth transistor 20 and the transistor 21 of the output circuit 8 illustrated in FIG. 1. The resistor 27 can limit currents I5 and I6 flowing when the fourth transistor 20 is turned on. The circuit operations except for this point is similar to the output circuit 8 illustrated in FIG. 1.

In the output circuit 8a, a resistance of the resistor 27 allows to suppress the consumption current of a steady state.

The voltage generator 6, the detector 7, and the compensator 16 are similar to those of the hot-swap controller 2.

The voltage generator 6 is supplied with the supply voltage VCC, supplies the first current I1 that varies depending on the supply voltage VCC to the first resistor 11 and the second resistor 12 via the connection node 13, and generates the first voltage Vb across the second resistor 12.

The detector 7 and the compensator 16 constitute a feedback circuit across the first resistor 11. The feedback circuit detects variation of the first voltage Vb with respect to the given value of the supply voltage VCC, feeds back the second current I2 to the one terminal of the first resistor 11 of the voltage generator 6 depending on the variation of the first voltage Vb, and compensates the first voltage Vb. The first transistor (detect transistor) 15 detects the variation of the first voltage Vb. The second transistor (feedback transistor) 16 feeds back the second current I2 to the one terminal of the first resistor 11 of the voltage generator 6 depending on the variation of the first voltage Vb detected by the first transistor 15 and compensates the first voltage Vb.

The first voltage Vb is generated by synthesizing the resultant current I3=I1+I2 of the second current I2 and the first current I1 supplied via the resistor 10. Therefore, the variation of the first voltage Vb is compensated to reduce variation, which may be caused by variation of production process, of the release voltage VRD.

As described above, the hot-swap controller 2a outputs the enabling signal PU3sOUT that becomes low level or high level depending on the value of the supply voltage VCC. The hot-swap controller 2a can compensate and reduce the variation of the release voltage VRD due to product process.

### Third Example of the Second Embodiment

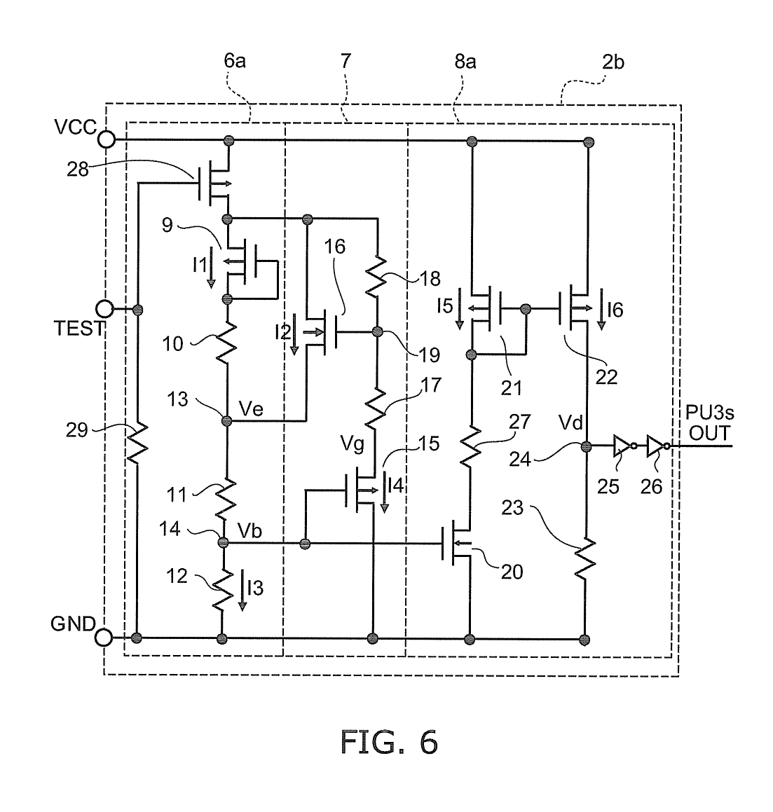

FIG. 6 is a circuit diagram illustrating another configuration of the hot-swap controller according to the second embodiment.

As illustrated in FIG. 6, the hot-swap controller 2b according to the second embodiment includes a voltage generator 6a, a detector 7, a compensator 16, and an output circuit 8a. The hot-swap controller 2b has a configuration in which the voltage generator 6 of the hot-swap controller 2a illustrated in FIG. 5 is replaced with a voltage generator 6a.

Similarly to the hot-swap controller 2a illustrated in FIG. 1, the hot-swap controller 2b can be used to control the interface circuit 3.

The voltage generator 6a includes a transistor (bias transistor) 9, a resistor 10, a first resistor 11, a second resistor 12, a transistor (switching element) 28, and a resistor 29. The voltage generator 6a has a configuration in which the transistor 28 and the resistor 29 are added to the voltage generator 6 illustrated in FIG. 2.

The transistor 9 is a PMOS, and its source is supplied with a supply voltage VCC via the transistor 28. The gate and the drain of the transistor 9 are connected to one terminal of the resistor 10. One other terminal of the resistor 10 is connected to one terminal of the first resistor 11. The transistor 9 and the resistor 10 are supplied with the supply voltage VCC and supply a first current I1 that varies depending on the supply voltage VCC to the one terminal (connection node 13) of the first resistor 11.

The second resistor 12 is connected between one other terminal of the first resistor 11 and a ground. The first resistor 11 and the second resistor 12 are connected in series. A first voltage Vb is generated across the second resistor 12.

The resistor 29 is connected between the gate of the transistor 28 and the ground. A test signal TEST is input to the gate of the transistor 28. When the test signal TEST is high level, the hot-swap controller 2b becomes a test state. The transistor 28 is turned off, and current between a power supply and the ground of the voltage generator 6a does not flow. Therefore, the hot-swap controller 2b outputs low level to an enabling signal PU3sOUT.

When the test signal TEST is low level, the hot-swap controller 2b becomes a normal operation state. The transistor 28 is turned on, and voltage generator 6a operates in the same manner as the voltage generator 6 illustrated in FIG. 1.

In the normal operation state, the voltage generator 6a is supplied with the supply voltage VCC, supplies the first current I1 that varies depending on the supply voltage VCC to the first resistor 11 and the second resistor 12 via the connection node 13, and generates the first voltage Vb across the second resistor 12.

The detector 7 and the compensator 16 constitute a feedback circuit across the first resistor 11. The feedback circuit detects variation of the first voltage Vb with respect to the given value of the supply voltage VCC, feeds back the second current I2 to the one terminal (connection node 13) of the first resistor 11 of the voltage generator 6 depending on the variation of the first voltage Vb, and compensates the first voltage Vb. The first transistor 15 detects the variation of the first voltage Vb. The second transistor 16 feeds back the current I2 to the voltage generator 6 depending on the variation of the first voltage Vb detected by the first transistor 15 and compensates the first voltage Vb.

The first voltage Vb is generated by synthesizing the resultant current I3=I1+I2 of the second current I2 and the first current I1 supplied via the resistor 10. Therefore, the first voltage Vb is compensated to reduce variation, which may be caused by variation of production process, of the release voltage VRD.

As described above, the hot-swap controller 2b outputs the enabling signal PU3sOUT depending on the value of the supply voltage VCC by setting the test signal to low level. The hot-swap controller 2b can compensate and reduce the variation of the release voltage VRD due to product process.

Further, the hot-swap controller 2b outputs low level to the enabling signal PU3sOUT by setting the test signal to high level and can shut down the interface circuit 3.

In the hot-swap controllers 2, 2a, and 2b, configurations in which the output circuits 8 and 8a include the inverters 25 and 26 are illustrated. However, one inverter may be sufficient in accordance with logic of the interface circuit 3 and the enabling signal PU3sOUT.

In the hot-swap controller 1, low level of the enabling signal PU3sOUT controls the interface circuit 3 to be disabled as a high impedance state; and high level of the enabling signal PU3sOUT controls the interface circuit 3 to be enabled by releasing the high impedance state. However, high level of the enabling signal PU3sOUT may control the interface circuit 3 to be disabled, and low level of the enabling signal PU3sOUT may control the interface circuit 3 to be enabled in accordance with logic of the interface circuit 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A hot-swap controller, comprising:
an output circuit configured to generate an enabling signal, the enabling signal being capable of switching an output signal of a semiconductor device provided in a hot-swap board to be disabled when a supply voltage is lower than a release voltage and to be enabled when the supply voltage is higher than the release voltage;
a voltage generator including a bias transistor supplied with the supply voltage and configured to generate a first voltage, the first voltage varying depending on the supply voltage and being referred to detect the release voltage;
a detector configured to detect the first voltage; and
a compensator configured to compensate the first voltage to a certain value depending on an output of the detector.

2. The controller according to claim 1, wherein the output circuit includes an output transistor configured to input the first voltage, and the output transistor is turned on at the supply voltage being the release voltage.

3. The controller according to claim 2, wherein the output circuit further includes an inverter configured to convert an output of the output transistor into a digital signal.

4. The controller according to claim 1, wherein the voltage generator further includes a first resistor and a second resistor connected in series between the bias transistor and a ground and between the compensator and the ground.

5. The controller according to claim 1, wherein the detector includes a detection transistor configured to generate current depending on the first voltage.

6. The controller according to claim 5, wherein the detection transistor is a P-channel MOSFET.

7. The controller according to claim 5, wherein the detector further includes a detection resistor connected to the detection transistor.

8. The controller according to claim 7, wherein the compensator is configured to feed back current to the voltage generator depending on a voltage of the detection resistor.

9. The controller according to claim 5, wherein the compensator includes a feedback transistor having a different channel type from the detection transistor and being configured to feed back current to the voltage generator depending on the output of the detector.

10. The controller according to claim 1, wherein the voltage generator further includes a switching element supplied with the supply voltage, and the bias transistor is supplied with the supply voltage via the switching element.

11. The controller according to claim 1, further comprising a 3-state circuit controlled in disable or enable by the enabling signal and configured to output the output signal of the semiconductor device provided on the hot-swap board.

12. The controller according to claim 11, wherein the output circuit includes an output transistor turned on at the supply voltage being the release voltage.

13. The controller according to claim 12, wherein the output circuit further includes an inverter configured to convert an output of the output transistor into a digital signal.

14. The controller according to claim 11, wherein the voltage generator includes a first resistor and a second resistor connected in series between the bias transistor and a ground and between the compensator and the ground.

15. The controller according to claim 11, wherein the detector includes a detection transistor configured to generate current depending on the first voltage.

16. The controller according to claim 15, wherein the detection transistor is a P-channel MOSFET.

17. The controller according to claim 15, wherein the detector further includes a detection resistor connected to the detection transistor.

18. The controller according to claim 17, wherein the compensator is configured to feed back current to the voltage generator depending on a voltage of the detection resistor.

19. The controller according to claim 15, wherein the compensator includes a feedback transistor having a different channel type from the detection transistor and being configured to feed back current to the voltage generator depending on the output of the detector.

20. The controller according to claim 11, wherein the voltage generator further includes a switching element supplied with the supply voltage, and the bias transistor is supplied with the supply voltage via the switching element.
